(19) United States
(12) Patent Application Publication
(10) Pub. No.: US 2025/0306457 A1
(43) Pub. Date: Oct. 2, 2025

(54) SEMICONDUCTOR PHOTORESIST COMPOSITIONS AND METHODS OF FORMING PATTERNS USING THE COMPOSITION

(71) Applicant: SAMSUNG SDI CO., LTD., Yongin-si (KR)

(72) Inventors: Minyoung LEE, Suwon-si (KR); Miyeon HAN, Suwon-si (KR); Eunmi KANG, Suwon-si (KR); Sumin JANG, Suwon-si (KR); Chungheon LEE, Suwon-si (KR); Minki CHON, Suwon-si (KR); Jihyun YOON, Suwon-si (KR); Seongyeon HWANG, Suwon-si (KR)

(21) Appl. No.: 19/030,799

(22) Filed: Jan. 17, 2025

(30) Foreign Application Priority Data
Mar. 28, 2024 (KR) 10-2024-0042667

(51) Int. Cl. G03F 7/004; G03F 7/16

(52) U.S. Cl. CPC G03F 7/0042; G03F 7/168

(57) ABSTRACT

A semiconductor photoresist composition and a method of forming patterns using the composition are disclosed. The semiconductor photoresist composition may include an organic tin (Sn) compound that may include a hydrolyzable ligand substituted with at least one deuterium and a solvent.

### CROSS-REFERENCE TO RELATED APPLICATION

The present application claims priority to and the benefit of Korean Patent Application No. 10-2024-0042667, filed on Mar. 28, 2024, in the Korean Intellectual Property Office, the entire disclosure of which is incorporated herein by reference.

### BACKGROUND

### 1. Field

One or more embodiments of the present disclosure relates to a semiconductor photoresist composition and a method of forming patterns using the semiconductor photoresist composition.

### 2. Description of the Related Art

Extreme ultraviolet (EUV) lithography has drawn significant attention as a technology for manufacturing a next generation semiconductor device. The EUV lithography is a pattern-forming technology using an EUV ray that has a wavelength of 13.5 nm as an exposure light source. According to the EUV lithography, a fine pattern (e.g., less than or equal to 20 nm) may be formed in an exposure process during a manufacture of a semiconductor device (e.g., a semiconductor chip).

The extreme ultraviolet (EUV) lithography may be realized through development of compatible photoresists which may be performed at a spatial resolution of less than or equal to 16 nm. Efforts to satisfy insufficient specifications of chemically amplified (CA) photoresists, such as a resolution, a photospeed, and feature roughness (or also referred to as a line edge roughness or LER), for the next generation device have been made.

An intrinsic image blurring due to an acid-catalyzed reaction in a polymer-type or kind photoresists limits a resolution in small feature sizes, which occurs in electron beam (e-beam) lithography. The chemically amplified (CA) photoresists are designed for high sensitivity. However, because their elemental makeups reduce light absorbance of the photoresists at a wavelength of 13.5 nm, it may decrease their sensitivity, and the chemically amplified (CA) photoresists may have more difficulties under an EUV exposure.

The CA photoresists may also have difficulties with respect to small feature sizes due to roughness issues, and line edge roughness (LER) of the CA photoresists experimentally may be increased as a photospeed is decreased partially due to an essence of acid catalyst processes. A novel high-performance photoresist is required or desired in a semiconductor industry because of these defects and problems of the CA photoresists.

In order to overcome the aforementioned drawbacks of the chemically amplified (CA) organic photosensitive composition, an inorganic photosensitive composition has been researched. The inorganic photosensitive composition has been mainly or predominantly used for negative tone patterning which has resistance against removal by a developer composition due to chemical modification through non-chemical amplification mechanism. The inorganic composition includes an inorganic element that has a higher EUV absorption rate than hydrocarbon, and thus, it may secure sensitivity through the non-chemical amplification mechanism and may be less sensitive with respect to a stochastic effect and thus may have low line edge roughness and a relatively smaller number of defects.

Inorganic photoresists based on peroxopolyacids of tungsten mixed with tungsten, niobium, titanium, and/or tantalum have been reported as radiation sensitive materials for patterning.

These materials may be effective for patterning large pitches for bilayer configuration as far ultraviolet (deep UV), X-ray, and electron beam sources. When cationic hafnium metal oxide sulfate (HfSOx) materials along with a peroxo complexing agent were used to image a 15 nm half-pitch (HP) through projection EUV exposure, relatively high performance was obtained. This system exhibits a relatively higher performance of a non-CA photoresist and has a practicable photospeed near to a requirement for an EUV photoresist. However, the hafnium metal oxide sulfate material including the peroxo complexing agent has some practical drawbacks. First, these materials are coated in a mixture of corrosive sulfuric acid/hydrogen peroxide and have insufficient shelf-life stability. Second, a structural change of the materials for performance improvement as a composite mixture is challenging. Third, development should be performed in a tetramethylammonium hydroxide (TMAH) solution at a relatively high concentration of 25 wt % and/or the like.

To address these issues, research has been focused on developing molecules that include tin (Sn) which have excellent or suitable absorption of extreme ultraviolet rays. As for an organic tin (Sn) polymer among the molecules containing tin (Sn), alkyl ligands are dissociated by light absorption or secondary electrons produced. The associated alkyl ligands are then crosslinked with adjacent chains through oxo bonds and thus enable the negative tone patterning which may not be removed by an organic developer. Although this organic tin (Sn) polymer exhibits greatly improved sensitivity and maintains a desired resolution and line edge roughness, it is still desirable to further improve the patterning characteristics for commercial availability.

### SUMMARY

One or more aspects of embodiments of the present disclosure are directed toward a semiconductor photoresist composition that has excellent sensitivity (or suitable sensitivity) and line edge roughness (LER) characteristics (or suitable LER characteristics) and improved coating properties (or suitable coating properties).

One or more aspects of embodiments of the present disclosure are directed toward a method of forming patterns using the semiconductor photoresist composition.

Additional aspects of embodiments will be set forth in part in the description which follows and, in part, will be apparent from the description, or may be learned by practice of the presented embodiments of the present disclosure.

A semiconductor photoresist composition according to one or more embodiments of the present disclosure may include an organic tin (Sn) compound that includes a hydrolyzable ligand substituted with at least one deuterium (or D or 2H; or at least one deuterium atom) and a solvent.

A method of forming patterns according to one or more embodiments of the present disclosure may include providing an etching-objective layer on a substrate, coating the semiconductor photoresist composition on the etching-objective layer and heating it at a temperature of about 110° C. to about 180° C. to form a photoresist layer, exposing and developing the photoresist layer to form a photoresist film having a photoresist pattern, and etching the etching-objective layer using the photoresist pattern acting or serving as an etching mask.

The semiconductor photoresist composition according to one or more embodiments of the present disclosure may realize excellent sensitivity (or suitable sensitivity) and excellent LER characteristics (or suitable LER characteristics), and a photoresist layer to which the photoresist composition is applied may maintain excellent coating properties (or suitable coating properties) even in a high temperature process.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1A-1E are cross-sectional views for illustrating a method of forming patterns using a semiconductor photoresist composition according to one or more embodiments of the present disclosure.

### DETAILED DESCRIPTION

The subject matter of the present disclosure may be modified in one or more suitable alternate forms, and thus example embodiments will be illustrated in the drawing and described in more detail. It should be understood, however, that it is not intended to limit the present disclosure to the particular forms disclosed, but rather, is intended to cover all modifications, equivalents, and alternatives falling within the spirit and scope of the present disclosure.

Hereinafter, referring to the drawings, one or more embodiments of the present disclosure are described in more detail. In the following description of the present disclosure, the functions or constructions that should be generally understood by a person of ordinary skill in the art may not be described in order to clarify the present disclosure.

In order to clearly illustrate embodiments of the present disclosure, certain description and relationships may be omitted, and throughout the present disclosure, the same (or substantially the same) or similar configuration elements may be designated by the same reference numerals. Also, because the size and thickness of each configuration shown in the drawings may be arbitrarily shown for better understanding and ease of description, embodiments of the present disclosure are not necessarily limited thereto.

In the drawings, the thickness of layers, films, panels, regions, and/or the like, may be enlarged for clarity. In the drawings, the thickness of a part of layers or regions, and/or the like, may be exaggerated for clarity. It will be understood that if (e.g., when) an element, such as a layer, film, region, or substrate, is referred to as being “on” another element, it may be directly on the other element or intervening elements may also be present. In one or more embodiments, if (e.g., when) an element is referred to as being “directly on” another element, there are no intervening elements present.

As utilized herein, the terms, “and/or” and “or,” may include any and all combinations of one or more of the associated listed items. Expressions, such as “at least one of,” when preceding a list of elements, may modify the entire list of elements and may not modify the individual elements of the list.

It will be further understood that the terms, “comprise,” “include,” or “have/has,” when utilized in the present disclosure, specify the presence of stated features, integers, steps, operations, elements, and/or components, but do not preclude the presence or addition of one or more other features, integers, steps, operations, elements, components, and/or groups thereof. The “/” utilized in the present disclosure may be interpreted as “and” or as “or” depending on the situation.

As utilized herein, the singular forms, “a,” “an,” and “the,” are intended to include the plural forms as well, unless the context clearly indicates otherwise. Further, the utilization of “may” when describing embodiments of the present disclosure refers to “one or more embodiments of the present disclosure”.

In the context of the present disclosure and unless otherwise defined, the terms, “use,” “using,” and “used,” may be considered synonymous with the terms, “utilize,” “utilizing,” and “utilized,” respectively.

As utilized herein, the term, “about,” or similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and may refer to being within an acceptable range of deviation for the particular value as determined by one of ordinary skill in the art, considering the measurement in question and the error associated with measurement of the particular quantity (e.g., the limitations of the measurement system). For example, “about” may refer to being within one or more standard deviations or within +30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art would appreciate, in view of the present disclosure in its entirety, that each suitable feature of the one or more embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

As used herein, “substituted” refers to replacement of a hydrogen atom by deuterium (or D or ²H), a halogen, a carboxyl group, a hydroxyl group, a thiol group, a cyano group, a nitro group, —NRR′ (wherein, R and R′ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, or a combination thereof. “Unsubstituted” refers to non-replacement of a hydrogen atom by another substituent and remaining of the hydrogen atom.

As used herein, if (e.g., when) a definition is not otherwise provided, “alkyl group” refers to a linear or branched aliphatic hydrocarbon group. The alkyl group may be “saturated alkyl group” without any double bond or triple bond.

The alkyl group may be a C1 to C8 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if (e.g., when) a definition is not otherwise provided, “cycloalkyl group” refers to a monovalent cyclic aliphatic hydrocarbon group.

The cycloalkyl group may be a C3 to C8 cycloalkyl group, for example, a C3 to C7 cycloalkyl group, a C3 to C6 cycloalkyl group, a C3 to C5 cycloalkyl group, or a C3 to C4 cycloalkyl group. For example, the cycloalkyl group may be a cyclopropyl group, a cyclobutyl group, a cyclopentyl group, or a cyclohexyl group, but embodiments of the present disclosure are not limited thereto.

As used herein, “aliphatic unsaturated organic group” refers to a hydrocarbon group including a bond in which the bond between the carbon and carbon atom in the molecule may be a double bond, a triple bond, or a combination thereof.

The aliphatic unsaturated organic group may be a C2 to C8 aliphatic unsaturated organic group. For example, the aliphatic unsaturated organic group may be a C2 to C7 aliphatic unsaturated organic group, a C2 to C6 aliphatic unsaturated organic group, a C2 to C5 aliphatic unsaturated organic group, or a C2 to C4 aliphatic unsaturated organic group. For example, the C2 to C4 aliphatic unsaturated organic group may be a vinyl group, an ethynyl group, an allyl group, a 1-propenyl group, a 1-methyl-1-propenyl group, a 2-propenyl group, a 2-methyl-2-propenyl group, a 1-propynyl group, a 1-methyl-1 propynyl group, a 2-propynyl group, a 2-methyl-2-propynyl group, a 1-butenyl group, a 2-butenyl group, a 3-butenyl group, a 1-butynyl group, a 2-butynyl group, or a 3-butynyl group.

As used herein, “aryl group” refers to a substituent in which all atoms in the cyclic substituent have a p-orbital and these p-orbitals are conjugated and may include a monocyclic, polycyclic or fused ring (e.g., rings sharing adjacent pairs of carbon atoms) functional groups.

As used herein, “heteroaryl group” may refer to aryl group including at least one heteroatom selected from among nitrogen (N), oxygen (O), sulfur(S), phosphorus (P), and silicon (Si). Two or more heteroaryl groups may be linked by a sigma bond directly, or if (e.g., when) the heteroaryl group includes two or more rings, the two or more rings may be fused. If (e.g., when) the heteroaryl group is a fused ring, each ring may include one to three heteroatoms.

As used herein, unless otherwise defined, “alkenyl group” refers to an aliphatic unsaturated alkenyl group including at least one double bond as a linear or branched aliphatic hydrocarbon group.

As used herein, unless otherwise defined, “alkynyl group” refers to an aliphatic unsaturated alkynyl group including at least one triple bond as a linear or branched aliphatic hydrocarbon group.

Hereinafter, a semiconductor photoresist composition according to one or more embodiments of the present disclosure is described.

The semiconductor photoresist composition according to one or more embodiments of the present disclosure may include an organic tin (Sn) compound that includes a hydrolyzable ligand substituted with at least one deuterium and a solvent. As used herein, “at least one deuterium” may refer to “at least one deuterium atom (D or ²H).

If (e.g., when) a deuterium-substituted ligand is used, coating properties may be improved in a high-temperature process (e.g., to be suitable coating properties in a high-temperature process), and the sensitivity of the photoresist to which it is applied may be improved (e.g., to provide suitable sensitivity of the photoresist).

The organic tin compound may be represented by Chemical Formula 1.

R¹₄₋ₙSnXₙ Chemical Formula 1

R¹ may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,

X may be a hydrolyzable group including at least one deuterium, and

n may be one of integers of 1 to 3.

For example, X may be selected from among an alkoxy or aryloxy group (—OR^{a}, wherein R^{a} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{b}, wherein R^{b} may be hydrogen, deuterium, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{c}R^{d}, wherein R^{c} and R^{d} may each independently be hydrogen, deuterium, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{e} (COR^{f}), wherein R^{e} and R^{f} may each independently be hydrogen, deuterium, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{g}C(NR^{h})Rⁱ, wherein R^{g}, R^{h}, and Rⁱ may each independently be hydrogen, deuterium, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{j}, wherein R^{j} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a thiocarboxyl group (—S(CO)R^{k}, wherein R^{k} may be hydrogen, deuterium, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof),

R^{a} and Rⁱ may each independently be substituted with at least one deuterium,

R^{b} and R^{k} may each independently be deuterium or substituted with at least one deuterium, and

at least one selected from R^{c} and R^{d}; at least one selected from R^{e} and R^{f}; and at least one selected from among R^{g}, R^{h}, and Rⁱ may each independently be deuterium or may each independently be substituted with at least one deuterium.

For example, X may be selected from among an alkoxy or aryloxy group (—OR^{a}, wherein R^{a} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{b}, wherein R^{b} may be hydrogen, deuterium, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and an amidato group (—NR^{e}(COR^{f}), wherein R^{e} and R^{f} may each independently be hydrogen, deuterium, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof),

R^{a} may be substituted with at least one deuterium,

R^{b} may be deuterium or substituted with at least one deuterium, and

R^{e} and R^{f} may each independently be deuterium or may each independently be substituted with at least one deuterium.

For example, the R^{a} and Rⁱ may each independently be a methyl group substituted with at least one deuterium, an ethyl group substituted with at least one deuterium, a propyl group substituted with at least one deuterium, a butyl group substituted with at least one deuterium, an isopropyl group substituted with at least one deuterium, a tert-butyl group substituted with at least one deuterium, a tert-pentyl group substituted with at least one deuterium, a 2,2-dimethylpropyl group substituted with at least one deuterium, a cyclopropyl group substituted with at least one deuterium, a cyclobutyl group substituted with at least one deuterium, a cyclopentyl group substituted with at least one deuterium, a cyclohexyl group substituted with at least one deuterium, an ethenyl group substituted with at least one deuterium, a propenyl group substituted with at least one deuterium, a butenyl group substituted with at least one deuterium, an ethynyl group substituted with at least one deuterium, a propynyl group substituted with at least one deuterium, a butynyl group substituted with at least one deuterium, a phenyl group substituted with at least one deuterium, a tolyl group substituted with at least one deuterium, a xylene group substituted with at least one deuterium, a benzyl group substituted with at least one deuterium, or a combination thereof,

R^{b} and R^{k} may each independently be deuterium, a methyl group substituted with at least one deuterium, an ethyl group substituted with at least one deuterium, a propyl group substituted with at least one deuterium, a butyl group substituted with at least one deuterium, an isopropyl group substituted with at least one deuterium, a tert-butyl group substituted with at least one deuterium, a tert-pentyl group substituted with at least one deuterium, a 2,2-dimethylpropyl group substituted with at least one deuterium, a cyclopropyl group substituted with at least one deuterium, a cyclobutyl group substituted with at least one deuterium, a cyclopentyl group substituted with at least one deuterium, a cyclohexyl group substituted with at least one deuterium, an ethenyl group substituted with at least one deuterium, a propenyl group substituted with at least one deuterium, a butenyl group substituted with at least one deuterium, an ethynyl group substituted with at least one deuterium, a propynyl group substituted with at least one deuterium, a butynyl group substituted with at least one deuterium, a phenyl group substituted with at least one deuterium, a tolyl group substituted with at least one deuterium, a xylene group substituted with at least one deuterium, a benzyl group substituted with at least one deuterium, or a combination thereof,

R^{c}, R^{d}, R^{e}, R^{f}, R^{g}, R^{h}, and Rⁱ may each independently be hydrogen, deuterium, a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted tert-pentyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof, and

at least one selected from R^{c} and R^{d}; at least one selected from R^{e} and R^{f}; and at least one selected from among R^{g}, R^{h}, and Rⁱ may each independently be deuterium, a methyl group substituted with at least one deuterium, an ethyl group substituted with at least one deuterium, a propyl group substituted with at least one deuterium, a butyl group substituted with at least one deuterium, an isopropyl group substituted with at least one deuterium, a tert-butyl group substituted with at least one deuterium, a tert-pentyl group substituted with at least one deuterium, a 2,2-dimethylpropyl group substituted with at least one deuterium, a cyclopropyl group substituted with at least one deuterium, a cyclobutyl group substituted with at least one deuterium, a cyclopentyl group substituted with at least one deuterium, a cyclohexyl group substituted with at least one deuterium, an ethenyl group substituted with at least one deuterium, a propenyl group substituted with at least one deuterium, a butenyl group substituted with at least one deuterium, an ethynyl group substituted with at least one deuterium, a propynyl group substituted with at least one deuterium, a butynyl group substituted with at least one deuterium, a phenyl group substituted with at least one deuterium, a tolyl group substituted with at least one deuterium, a xylene group substituted with at least one deuterium, a benzyl group substituted with at least one deuterium, or a combination thereof.

The deuterium substitution rate of the hydrolyzable ligand may be about 1 to about 100%.

In one or more embodiments, the deuterium substitution rate may be about 5 to about 90%, for example, about 10 to about 75%, and, for example, about 20 to about 65%.

In the present disclosure, the term, “deuterium substitution rate” may refer to [(the number of deuteriums (or the number of deuterium atoms) included in the corresponding ligand)/(the maximum number of hydrogens (or the maximum number of hydrogen atoms) that the corresponding ligand may have)].

In the present disclosure, the term, “N % deuteration,” may refer to that N % of available hydrogens in a corresponding structure is substituted with deuterium.

For example, the term, “100% substitution with deuterium in acetamide,” may refer to that four hydrogens (or four hydrogen atoms) of the acetamide, except for those at bonding positions with the metal, may be all substituted with deuterium (or deuterium atoms).

In the present disclosure, a degree of the deuteration may be confirmed or characterized by a generally used or generally available measurement method, such as nuclear magnetic resonance spectroscopy (¹H-NMR), GC/MS, and/or the like.

The hydrolyzable ligand may be one or more functional groups that are derived from propionic acid, 4-methyl-2-pentanol (MIBC), propylene glycol monomethyl ether acetate (PGMEA), propylene glycol monomethyl ether (PGME), furoic acid, diethyl amine, and/or methyl isobutyrate.

The semiconductor photoresist composition according to one or more embodiments of the present disclosure may include an organic tin (Sn) compound that has a hydrolytic ligand (e.g., a hydrolyzable ligand) substituted with deuterium, resulting in improved sensitivity of a photoresist (e.g., suitable sensitivity of a photoresist).

The organic tin (Sn) compound may strongly or suitably absorb extreme ultraviolet rays at about 13.5 nm and thus have excellent or suitable sensitivity to light having a relatively high energy.

The semiconductor photoresist composition according to one or more embodiments of the present disclosure may include the organic tin (Sn) compound in an amount of about 0.5 wt % to about 30 wt %, for example, about 1 wt % to about 30 wt %, about 1 wt % to about 25 wt %, for example, about 1 wt % to about 20 wt %, for example, about 1 wt % to about 15 wt %, for example, about 1 wt % to about 10 wt %, or for example, about 1 wt % to about 5 wt % based on about 100 wt % of the semiconductor photoresist composition. In one or more embodiments, an amount of the organic tin (Sn) compound may be about 0.5 wt % to about 30 wt % based on 100 wt % of the semiconductor photoresist composition. If (e.g., when) the organic tin (Sn) compound is included within the ranges, storage stability and etch resistance of the semiconductor photoresist composition may be improved or may become suitable, and resolution characteristics also may be enhanced or may become suitable.

Because the semiconductor photoresist composition according to one or more embodiments of the present disclosure may include the organic tin compound as described in one or more embodiments, it may provide a semiconductor photoresist composition that has excellent sensitivity (or suitable sensitivity) and pattern formation properties (or suitable pattern formation properties).

The solvent may include in the semiconductor photoresist composition according to one or more embodiments of the present disclosure may be an organic solvent, and may be, for example, an aromatic compound (e.g., xylene, toluene, and/or the like), an alcohol (e.g., 4-methyl-2-pentanol, 4-methyl-2-propanol, 1-butanol, methanol, isopropyl alcohol, 1-propanol, and/or the like), an ether (e.g., anisole, tetrahydrofuran, and/or the like), an ester (n-butyl acetate, propylene glycol monomethyl ether acetate (PGMEA), ethyl acetate, ethyl lactate, and/or the like), a ketone (e.g., methyl ethyl ketone, 2-heptanone, and/or the like), or a mixture thereof, but embodiments of the present disclosure are not limited thereto.

In one or more embodiments, the semiconductor photoresist composition may further include a resin in addition to the organic tin (Sn) compound and solvent as described in one or more embodiments of the present disclosure.

The resin may be a phenol-based resin including at least one aromatic moiety selected from moieties listed in Group 2.

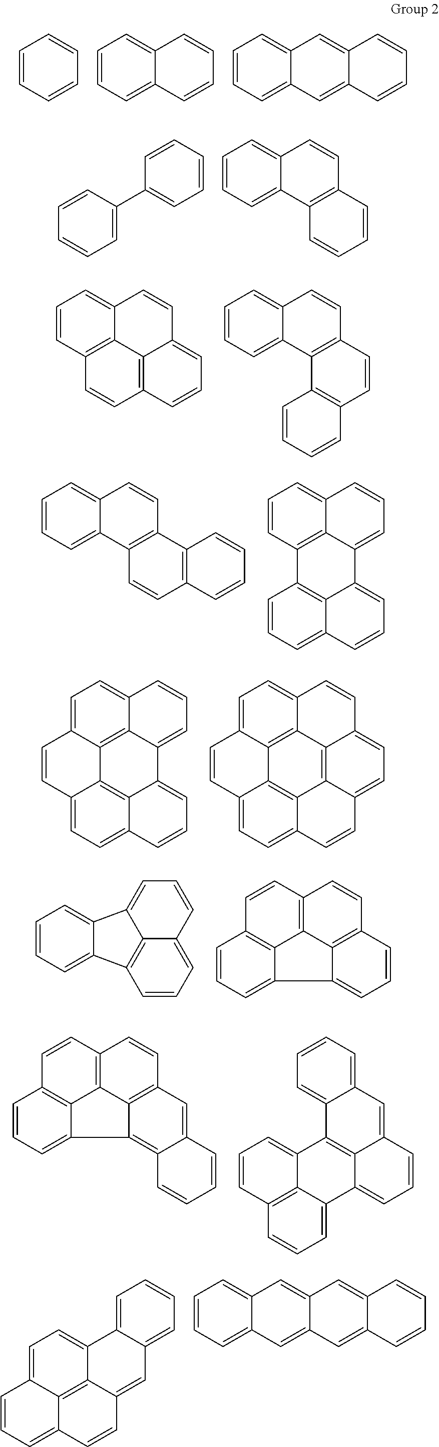

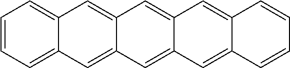 [SMILES: c1ccc2cc3cc4cc5ccccc5cc4cc3cc2c1]

The resin may have a weight average molecular weight of about 500 g/mol to about 20,000 g/mol.

The resin may be in an amount of about 0.1 wt % to about 50 wt % based on a total amount of the semiconductor photoresist composition.

If (e.g., when) the resin is in the amount range according to one or more embodiments of the present disclosure, it may have excellent etch resistance (or suitable etch resistance) and heat resistance (or suitable heat resistance).

In one or more embodiments, the semiconductor photoresist composition according to one or more embodiments may consist of the organic tin (Sn) compound, solvent, and resin as described in one or more embodiments of the present disclosure. The semiconductor photoresist composition according to the one or more embodiments of the present disclosure may further include additives as needed or desired. Examples of the additives may be a surfactant, a crosslinking agent, a leveling agent, an organic acid, a quencher, or a combination thereof.

The surfactant may include, for example, alkyl benzene sulfonate salt, alkyl pyridinium salt, polyethylene glycol, a quaternary ammonium salt, or a combination thereof, but embodiments of the present disclosure are not limited thereto.

The crosslinking agent may be, for example, a melamine-based crosslinking agent, a substituted urea-based crosslinking agent, an acryl-based crosslinking agent, an epoxy-based crosslinking agent, or a polymer-based crosslinking agent, but embodiments of the present disclosure are not limited thereto. It may be a crosslinking agent that has at least two crosslinking forming substituents, for example, a compound, such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl) tetramethyldisiloxane, methoxymethylated urea, butoxymethylated urea, methoxymethylated thiourea, and/or the like.

The leveling agent may be used for improving coating flatness during printing and may be a commercially available leveling agent.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof, but embodiments of the present disclosure are not limited thereto.

The quencher may be diphenyl(p-tolyl) amine, methyl diphenyl amine, triphenyl amine, phenylenediamine, naphthylamine, diaminonaphthalene, or a combination thereof.

A use amount of the additives may be controlled depending on desired properties.

The semiconductor photoresist composition may further include a silane coupling agent acting or serving as an adherence enhancer in order to improve a close-contacting force with the substrate (e.g., in order to improve adherence of the semiconductor photoresist composition to the substrate). The silane coupling agent may be, for example, a silane compound including a carbon-carbon unsaturated bond, such as vinyltrimethoxysilane, vinyl triethoxysilane, vinyl trichlorosilane, vinyl tris(β-methoxyethoxy) silane; and/or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy [3-(phenylamino) propyl]silane, and/or the like, but embodiments of the present disclosure are not limited thereto.

The semiconductor photoresist composition may be formed into a pattern having a high aspect ratio without a collapse. In one or more embodiments, in order to form a fine pattern having a width (e.g., a line width) of, for example, about 5 nm to about 100 nm, for example, about 5 nm to about 80 nm, for example, about 5 nm to about 70 nm, for example, about 5 nm to about 50 nm, for example, about 5 nm to about 40 nm, for example, about 5 nm to about 30 nm, for example, or about 5 nm to about 20 nm, the semiconductor photoresist composition may be used for a photoresist process using light having a wavelength in a range from about 5 nm to about 150 nm, for example, about 5 nm to about 100 nm, about 5 nm to about 80 nm, about 5 nm to about 50 nm, about 5 nm to about 30 nm, about 5 nm to about 20 nm, or about 5 nm to about 10 nm. In one or more embodiments, the semiconductor photoresist composition according to one or more embodiments may be used to realize extreme ultraviolet lithography using an EUV light source of a wavelength of about 13.5 nm.

According to one or more embodiments of the present disclosure, a method of forming patterns using the semiconductor photoresist composition as described in one or more embodiments may be provided. For example, the manufactured pattern may be a photoresist pattern.

The method of forming patterns according to one or more embodiments may include providing an etching-objective layer on a substrate, coating the semiconductor photoresist composition on the etching-objective layer and heating it at a temperature of about 110° C. to about 180° C. to form a photoresist layer, exposing and developing the photoresist layer to form a photoresist film having a photoresist pattern and etching the etching-objective layer using the photoresist pattern acting or serving as an etching mask.

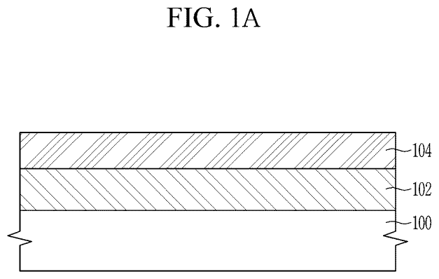

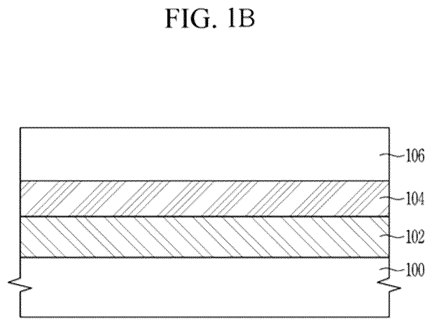

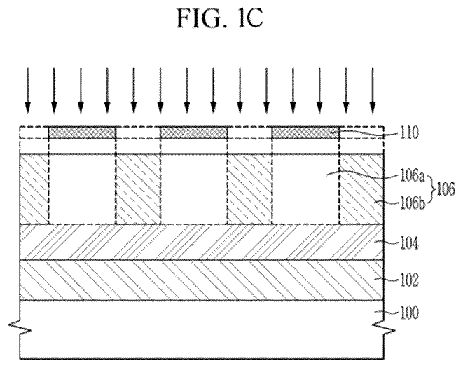

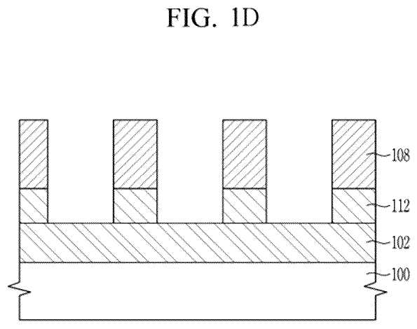

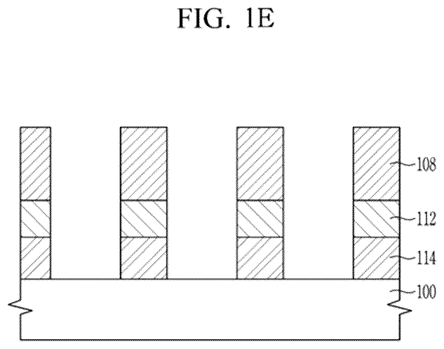

Hereinafter, an embodiment of a method of forming patterns using the semiconductor photoresist composition may be described referring to FIGS. 1A-1E. FIGS. 1A-1E are cross-sectional views for illustrating a method of forming patterns using a semiconductor photoresist composition according to one or more embodiments of the present disclosure.

Referring to FIG. 1A, an object for etching (e.g., etching objective layer or etching-target layer) may be prepared. The object for etching may be a thin film 102 on a semiconductor substrate 100. Hereinafter, the object for etching may be limited to the thin film 102. A surface of the thin film 102 may be washed to remove impurities and/or the like remaining thereon. The thin film 102 may be, for example, a silicon nitride layer, a polysilicon layer, and/or a silicon oxide layer.

Subsequently, the resist underlayer composition for providing a resist underlayer 104 may be spin-coated on the surface of the washed thin film 102. However, embodiments of the present disclosure are not limited thereto, and one or more suitable coating methods, for example, a spray coating, a dip coating, a knife edge coating, a printing method, for example, an inkjet printing and/or a screen printing, and/or the like may be used.

Description of the coating process of the resist underlayer may not be repeated, and hereinafter, a process including a coating of the resist underlayer may be described.

Then, the coated composition may be dried and baked to form a resist underlayer 104 on the thin film 102. The baking may be performed at about 100° C. to about 500° C., for example, about 100° C. to about 300° C.

The resist underlayer 104 may be formed between the substrate 100 and a photoresist layer 106 and thus may prevent non-uniformity (e.g., substantial non-uniformity) and pattern formability (or reduce a degree or occurrence of non-uniformity (e.g., substantial non-uniformity) and/or reduce pattern formability) of a photoresist line width that may otherwise occur if (e.g., when) a ray reflected from on the interface between the substrate 100 and the photoresist layer 106 and/or a hardmask between layers is scattered into an unintended photoresist region.

Referring to FIG. 1B, the photoresist layer 106 may be formed by coating the semiconductor photoresist composition on the resist underlayer 104. The photoresist layer 106 may be obtained by coating the semiconductor photoresist composition according to one or more embodiments of the present disclosure on the thin film 102 on the substrate 100 and then, curing it through a heat treatment.

For example, the formation of a pattern by using the semiconductor photoresist composition may include coating the semiconductor resist composition on the substrate 100 that has the thin film 102 through spin coating, slit coating, inkjet printing, and/or the like and then, drying it to form the photoresist layer 106.

The semiconductor photoresist composition has already been illustrated in more detail in one or more embodiments of the present disclosure and may not be illustrated again hereinafter.

Subsequently, a substrate 100 having the photoresist layer 106 may be subjected to a first baking (thermal treatment) process. The first baking process may be performed at about 110° C. to about 180° C.

The first baking process may be performed at, for example, about 130° C. to about 180° C., and for example, about 130° C. to about 160° C.

The root mean square roughness (R^{a}) of the photoresist layer after the first baking process has been completed may be less than about 0.4.

In one or more embodiments, the photoresist layer may include a tin (Sn)-oxygen (O)-tin (Sn) bond and/or a tin (Sn)-oxygen (O)-deuterium (D) bond.

Referring to FIG. 1C, the photoresist layer 106 may be selectively exposed using a patterned mask 110.

For example, the exposure may use an activation radiation including light or beam having a relatively high energy wavelength, such as EUV (extreme ultraviolet; a wavelength of about 13.5 nm), an E-Beam (an electron beam), and/or the like, as well as light or beam having a relatively short wavelength, such as an i-line (a wavelength of about 365 nm), a KrF excimer laser (a wavelength of about 248 nm), an ArF excimer laser (a wavelength of about 193 nm), and/or the like.

For example, light or beam for the exposure according to one or more embodiments may have a relatively short wavelength in a range from about 5 nm to about 150 nm and/or a relatively high energy wavelength, for example, EUV (extreme ultraviolet; a wavelength of 13.5 nm), an E-Beam (an electron beam), and/or the like.

The exposed region 106b of the photoresist layer 106 may have a different solubility from the unexposed region 106a of the photoresist layer 106 by forming a polymer by a crosslinking reaction, such as a condensation reaction between organometallic compounds.

In one or more embodiments, after exposure, the photoresist pattern may include a tin (Sn)-oxygen (O)-tin (Sn) bond and/or a tin (Sn)-oxygen (O)-deuterium (D) bond.

Subsequently, the substrate 100 may be subjected to a second baking process. The second baking process may be performed at a temperature of about 90° C. to about 200° C. The exposed region 106b of the photoresist layer 106 may become easily indissoluble regarding a developer due to the second baking process.

In FIG. 1D, the unexposed region 106a of the photoresist layer may be dissolved and removed using the developer to form a photoresist pattern 108. For example, the unexposed region 106a of the photoresist layer may be dissolved and removed by using an organic solvent, such as 2-heptanone and/or the like, to complete a photoresist pattern 108 corresponding to the negative tone image.

According to one or more embodiments of the present disclosure, a developer used in a method of forming patterns according to one or more embodiments of the present disclosure may be an organic solvent. The organic solvent used in the method of forming patterns according to one or more embodiments may be, for example, a ketone, such as methylethylketone, acetone, cyclohexanone, 2-heptanone, and/or the like, an alcohol, such as 4-methyl-2-propanol, 1-butanol, isopropanol, 1-propanol, methanol, and/or the like, an ester, such as propylene glycol monomethyl ether acetate (PGMEA), ethyl acetate, ethyl lactate, n-butyl acetate, butyrolactone, and/or the like, an aromatic compound, such as benzene, xylene, toluene, and/or the like, or a combination thereof.

However, the photoresist pattern according to one or more embodiments of the present disclosure may not be necessarily limited to the negative tone image but may be formed to have a positive tone image. In one or more embodiments, a developer used for forming the positive tone image may be a quaternary ammonium hydroxide composition, such as tetraethylammonium hydroxide, tetrapropylammonium hydroxide, tetrabutylammonium hydroxide, or a combination thereof.

According to one or more embodiments of the present disclosure, exposure to light or beam having a relatively high energy wavelength, such as EUV (extreme ultraviolet; a wavelength of 13.5 nm), an E-Beam (an electron beam), and/or the like, as well as light or beam having a relatively short wavelength, such as i-line (wavelength of about 365 nm), KrF excimer laser (wavelength of about 248 nm), ArF excimer laser (wavelength of about 193 nm), and/or the like, may provide a photoresist pattern 108 having a width of a thickness of about 5 nm to about 100 nm. For example, the photoresist pattern 108 may have a width of a thickness of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or about 5 nm to about 10 nm.

In one or more embodiments, the photoresist pattern 108 may have a pitch having (or with) a half-pitch of less than or equal to about 50 nm, for example, less than or equal to about 40 nm, for example, less than or equal to about 30 nm, for example, less than or equal to about 20 nm, or, for example, less than or equal to about 10 nm, and a line width roughness of less than or equal to about 5 nm, less than or equal to about 3 nm, less than or equal to about 2 nm, or less than or equal to about 1 nm.

According to one or more embodiments of the present disclosure, a photoresist film manufactured by the method of forming patterns as described in one or more embodiments of the present disclosure may be provided.

Then, the resist underlayer 104 may be etched using the photoresist pattern 108 formed on the photoresist film acting or serving as an etching mask. The organic layer pattern 112 may be formed through the etching process according to one or more embodiments of the present disclosure. The organic layer pattern 112 may also have a width (e.g., a line width) corresponding to that of the photoresist pattern 108.

Referring to FIG. 1E, the exposed thin film 102 may be etched by applying the photoresist pattern 108 acting or serving as an etching mask. As a result, the thin film may be formed acting or serving as a thin film pattern 114.

The etching of the thin film 102 may be, for example, dry etching using an etching gas and the etching gas may be, for example, CHF₃, CF₄, Cl₂, BCl₃, and/or a mixed gas thereof.

In the exposure process, the thin film pattern 114 formed by using the photoresist pattern 108 formed through the exposure process performed by using an EUV light source may have a width (e.g., a line width) corresponding to that of the photoresist pattern 108. For example, the thin film pattern 114 may have a width (e.g., line width) of about 5 nm to about 100 nm which may be equal to that of the photoresist pattern 108. For example, the thin film pattern 114 formed by using the photoresist pattern 108 formed through the exposure process performed by using an EUV light source may have a width (e.g., a line width) of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, and, for example, a width (e.g., line width) of less than or equal to about 20 nm, like that of the photoresist pattern 108.

Hereinafter, the subject matter of the present disclosure will be described in more detail through examples of the preparation of the semiconductor photoresist composition according to one or more embodiments of the present disclosure. However, embodiments the present disclosure are not technically restricted by the following examples.

### Synthesis of Organometallic Compound

### Synthesis Example 1

In a 250 mL 2-necked round-bottom flask, 20 g (51.9 mmol) of Ph₃SnCl was dissolved in 70 mL of tetrahydrofuran (THF) and then, cooled to 0° C. in an ice bath. Subsequently, a 1 M butyl magnesium chloride (BuMgCl) THF solution (62.3 mmol) was slowly added in a dropwise fashion thereto. When the dropwise addition was completed, the resultant was stirred at 25° C. for 12 hours, obtaining a compound represented by Chemical Formula 2a.

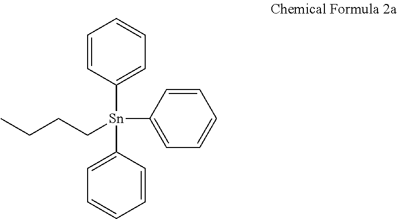 [SMILES: CCC[CH2][Sn]([c]1ccccc1)([c]1ccccc1)[c]1ccccc1]

Then, 10 g (24.6 mmol) of the compound Chemical Formula 2a was dissolved in 50 mL of methylene chloride (CH₂Cl₂), and 3 equivalents (73.7 mmol) of a 2 M hydrochloric acid solution (in diethyl ether) was slowly added in a dropwise fashion thereto at −78° C. for 30 minutes. Subsequently, after stirring at 25° C. for 12 hours, the resultant was concentrated and vacuum-distilled, obtaining a compound represented by Chemical Formula 2b.

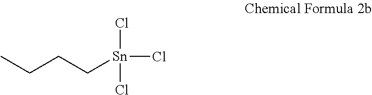

Then, 25 mL of acetic acid substituted with D (deuterium) was slowly added in a dropwise fashion to 10 g (25.6 mmol) of the compound represented by Chemical Formula 2b and then, refluxed by heating at 25° C. for 12 hours. After increasing the temperature to 25° C., the acetic acid was vacuum-distilled, finally obtaining a compound represented by Chemical Formula 2.

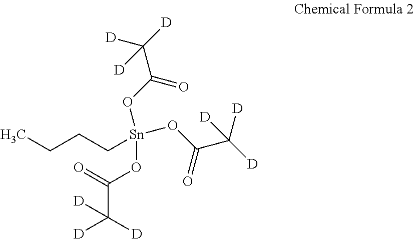 [SMILES: [2H]C([2H])([2H])C(=O)[O][Sn]([CH2]CCC)([O]C(=O)C([2H])([2H])[2H])[O]C(=O)C([2H])([2H])[2H]]

### Synthesis Example 2

A compound represented by Chemical Formula 3 was obtained in the same (or substantially the same) manner as in Synthesis Example 1 except that benzoic acid substituted with D (deuterium) was used instead of the acetic acid substituted with D (deuterium).

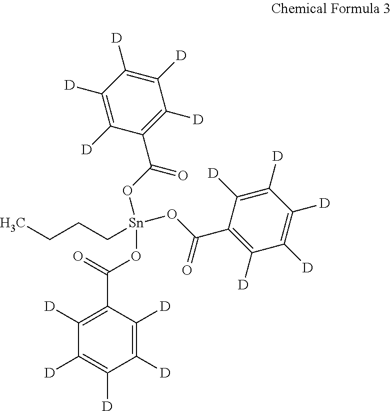 [SMILES: [2H]c1c([2H])c([2H])c(C(=O)[O][Sn]([CH2]CCC)([O]C(=O)c2c([2H])c([2H])c([2H])c([2H])c2[2H])[O]C(=O)c2c([2H])c([2H])c([2H])c([2H])c2[2H])c([2H])c1[2H]]

### Synthesis Example 3

A compound represented by Chemical Formula 4 was obtained in the same (or substantially the same) manner as in Synthesis Example 1 except that diethyl amine substituted with D (deuterium) was used instead of the acetic acid substituted with D (deuterium).

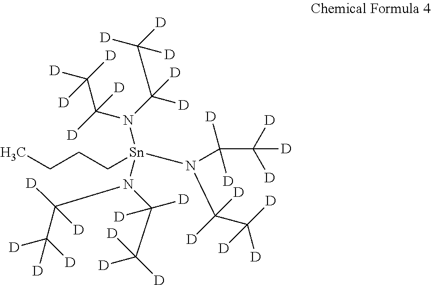 [SMILES: [2H]C([2H])([2H])C([2H])([2H])[N](C([2H])([2H])C([2H])([2H])[2H])[Sn]([CH2]CCC)([N](C([2H])([2H])C([2H])([2H])[2H])C([2H])([2H])C([2H])([2H])[2H])[N](C([2H])([2H])C([2H])([2H])[2H])C([2H])([2H])C([2H])([2H])[2H]]

### Synthesis Example 4

A compound represented by Chemical Formula 5 was obtained in the same (or substantially the same) manner as in Synthesis Example 1 except that 4-methyl-2-pentanol substituted with D (deuterium) was used instead of the acetic acid substituted with D (deuterium).

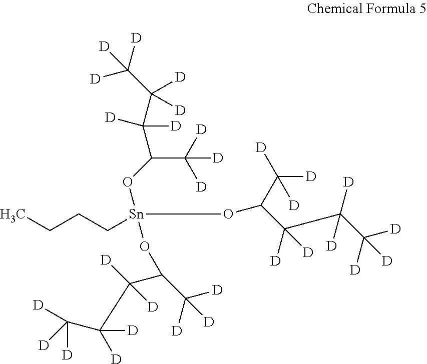 [SMILES: [2H]C([2H])([2H])C([O][Sn]([CH2]CCC)([O]C(C([2H])([2H])[2H])C([2H])([2H])C([2H])([2H])C([2H])([2H])[2H])[O]C(C([2H])([2H])[2H])C([2H])([2H])C([2H])([2H])C([2H])([2H])[2H])C([2H])([2H])C([2H])([2H])C([2H])([2H])[2H]]

### Synthesis Example 5

A compound represented by Chemical Formula 6 was obtained in the same (or substantially the same) manner as in Synthesis Example 1 except that propylene glycol ether substituted with D (deuterium) was used instead of the acetic acid substituted with D (deuterium).

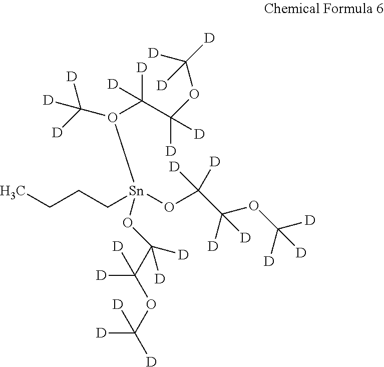 [SMILES: [2H]C([2H])([2H])OC([2H])([2H])C([2H])([2H])[O][Sn]([CH2]CCC)([O]C([2H])([2H])C([2H])([2H])OC([2H])([2H])[2H])<-[O](C([2H])([2H])[2H])C([2H])([2H])C([2H])([2H])OC([2H])([2H])[2H]]

### Synthesis Example 6

A compound represented by Chemical Formula 7 was obtained in the same (or substantially the same) manner as in Synthesis Example 1 except that acetic acid was used instead of the acetic acid substituted with D (deuterium).

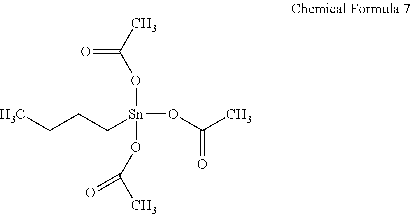 [SMILES: CCC[CH2][Sn]([O]C(C)=O)([O]C(C)=O)[O]C(C)=O]

### Synthesis Example 7

A compound represented by Chemical Formula 8 was obtained in the same (or substantially the same) manner as in Synthesis Example 1 except that benzoic acid was used instead of the acetic acid substituted with D (deuterium).

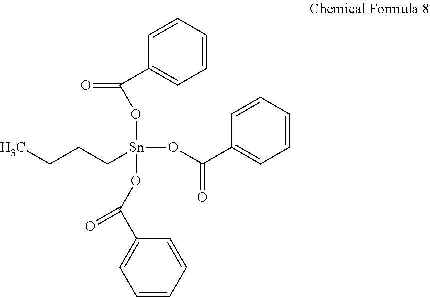 [SMILES: CCC[CH2][Sn]([O]C(=O)c1ccccc1)([O]C(=O)c1ccccc1)[O]C(=O)c1ccccc1]

### Synthesis Example 8

A compound represented by Chemical Formula 9 was obtained in the same (or substantially the same) manner as in Synthesis Example 1 except that diethyl amine was used instead of the acetic acid substituted with D (deuterium).

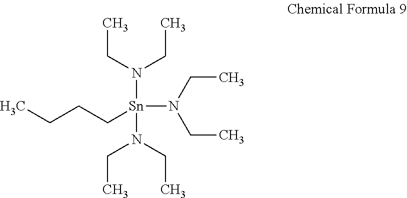 [SMILES: CCC[CH2][Sn]([N](CC)CC)([N](CC)CC)[N](CC)CC]

### Synthesis Example 9

A compound represented by Chemical Formula 10 was obtained in the same (or substantially the same) manner as in Synthesis Example 1 except that 4-methyl-2-pentanol was used instead of the acetic acid substituted with D (deuterium).

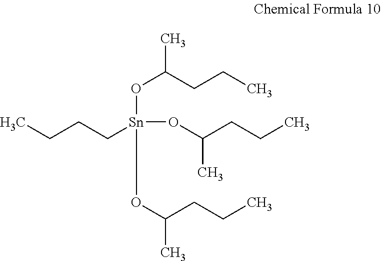 [SMILES: CCC[CH2][Sn]([O]C(C)CCC)([O]C(C)CCC)[O]C(C)CCC]

### Synthesis Example 10

A compound represented by Chemical Formula 11 was obtained in the same (or substantially the same) manner as in Synthesis Example 1 except that propylene glycol ether was used instead of the acetic acid substituted with D (deuterium).

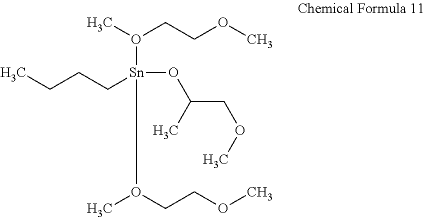 [SMILES: CCC[CH2][Sn]([O]C(C)COC)(<-[O](C)CCOC)<-[O](C)CCOC]

### Preparation of Semiconductor Photoresist Compositions

### Examples 1 to 5 and Comparative Examples 1 to 5

Each of the organic tin (Sn) compounds of Synthesis Example 1 to 10 was dissolved in a solvent (propylene glycol methyl ether acetate (PGMEA) or 4-Methyl-2-pentanol (MIBC)) described in Table 1 at a concentration of 3 wt % and then, filtered with a 0.1 μm polytetrafluoroethylene (PTFE) syringe filter, preparing a semiconductor photoresist composition.

TABLE 1

| | Organic tin compound | Solvent |
|---|---|---|
| Example 1 | Chemical Formula 2 | PGMEA |
| Example 2 | Chemical Formula 3 | PGMEA |
| Example 3 | Chemical Formula 4 | PGMEA |
| Example 4 | Chemical Formula 5 | MIBC |
| Example 5 | Chemical Formula 6 | PGMEA |
| Comparative Example 1 | Chemical Formula 7 | PGMEA |
| Comparative Example 2 | Chemical Formula 8 | PGMEA |
| Comparative Example 3 | Chemical Formula 9 | PGMEA |
| Comparative Example 4 | Chemical Formula 10 | MIBC |
| Comparative Example 5 | Chemical Formula 11 | PGMEA |

### Evaluation 1: Evaluation of Sensitivity

Each of the photoresist compositions according to the examples and the comparative examples was spin-coated for 60 seconds at 1500 rpm, respectively, on a 200 mm circular silicon wafer whose surface was deposited with hexamethyldisiloxane (HMDS), and baked at 110° C. for 60 seconds (baked after application, (post-apply baked (PAB)).

Subsequently, the wafer coated with the photoresist composition was irradiated by EUV light. Herein, the EUV light was applied in an increasing dose to each pad by adjusting pad exposure time.

Subsequently, the resist and the substrate were baked at 170° C. on a hot plate for 60 seconds after the exposure. The baked film was dipped in a developing solution (2-heptanone) for 30 seconds, washed with the developing solution for 10 seconds to remove a non-exposed coating region, and baked at 150° C. on a hot plate for 2 minutes, finally forming a L/S pattern (1:1).

An ellipsometer was used to measure a residual resist thickness of the exposed pad. Each residual thickness at each exposure dose was measured and then, graphed as a function to each exposure dose to measure sensitivity of the film, and the results are shown in Table 2.

### Evaluation 2: Evaluation of Process Stability

Each of the photoresist compositions according to the examples and the comparative examples was spin-coated at 1500 rpm for 60 seconds on a 200 mm circular silicon wafer whose surface was deposited with HMDS and baked at 130° C. and 160° C., respectively, for 60 seconds (baked after application, post-apply bake (PAB)) to form a thin film, which was taken an image of with an atomic force microscope (AFM), and the image was used to measure surface roughness of the thin film by using a software (e.g., Optical Profiler), and the results are shown in Table 2.

If Rq, which indicates surface roughness of a coating thin film, was less than 0.4 and concurrently (e.g., simultaneously), had a small change, although baked to a high temperature, the thin film was evaluated to have excellent process stability (or suitable process stability).

A variation ratio of the surface roughness was calculated according to Equation 1.

$$Rate of change of surface roughness value = [ \{ ( Rq at PAB at 160 ° C . ) - ( Rq at PAB at 130 ° C . ) \} / ( Rq at PAB at 130 ° C . ) ] \times 100 \qquad Equation 1$$

TABLE 2

| | Energy | Surface roughness (Rq) | | |
|---|---|---|---|---|
| | of | | | Rate of change |
| | optimum | | | of surface |
| | (Eop) | PAB | PAB | roughness value |
| | (mJ/cm²) | (130° C.) | (160° C.) | (%) |
| Example 1 | 80 | 0.25 | 0.27 | 8 |
| Example 2 | 85 | 0.30 | 0.33 | 10 |
| Example 3 | 87 | 0.35 | 0.36 | 3 |
| Example 4 | 70 | 0.28 | 0.31 | 11 |
| Example 5 | 86 | 0.31 | 0.34 | 10 |
| Comparative | 90 | 0.30 | 0.52 | 73 |
| Example 1 | | | | |
| Comparative | 94 | 0.36 | 0.74 | 106 |
| Example 2 | | | | |
| Comparative | 92 | 0.38 | 1.20 | 216 |
| Example 3 | | | | |
| Comparative | 88 | 0.33 | 0.56 | 70 |
| Example 4 | | | | |
| Comparative | 95 | 0.40 | 3.00 | 650 |
| Example 5 | | | | |

Referring to the results of Table 2, the patterns formed by using the photoresist compositions for a semiconductor according to Examples 1 to 5, compared with those formed by using the photoresist compositions for a semiconductor according to Comparative Examples 1 to 5, exhibited excellent sensitivity characteristics and also secured excellent coating properties by maintaining surface roughness of less than 0.4, even when a high temperature process was applied thereto, and concurrently (e.g., simultaneously), having a small variation ratio of the surface roughness according to the temperature increase.

Hereinbefore, certain embodiments have been described and illustrated, however, it should be apparent to a person having ordinary skill in the art that the present disclosure is not limited to disclosed embodiments of the present disclosure, and may be suitably modified and transformed without departing from the spirit and scope of the present disclosure. In one or more embodiments, the modified or transformed embodiments as such may not be understood separately from the technical ideas and aspects of one or more embodiments of the present disclosure, and the modified embodiments may be within the scope of the appended claims of the present disclosure and equivalents thereof.

Description of Symbols

| | |
|---|---|
| 100: substrate | 102: thin film |
| 104: resist underlayer | 106: photoresist layer |
| 106a: unexposed region | 106b: exposed region |
| 108: photoresist pattern | 112: organic layer pattern |
| 110: patterned mask | 114: thin film pattern |

What is claimed is:

1. A semiconductor photoresist composition, comprising:
an organic tin (Sn) compound comprising a hydrolyzable ligand substituted with at least one deuterium; and
a solvent.

2. The semiconductor photoresist composition as claimed in claim 1, wherein:
the organic tin (Sn) compound is represented by Chemical Formula 1:
R¹₄₋ₙSnXₙ Chemical Formula 1
wherein R¹ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
X is a hydrolyzable group comprising at least one deuterium, and
n is an integer of 1 to 3.

3. The semiconductor photoresist composition as claimed in claim 2, wherein:
X is selected from among an alkoxy or aryloxy group (—OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{b}, wherein R^{b} is hydrogen, deuterium, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{c}R^{d}, wherein R^{c} and R^{d} are each independently hydrogen, deuterium, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{e}(COR^{f}), wherein R^{e} and R^{f} are each independently hydrogen, deuterium, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{g}C(NR^{h})Rⁱ, wherein R^{g}, R^{h}, and Rⁱ are each independently hydrogen, deuterium, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{j}, wherein R^{j} is substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a thiocarboxyl group (—S(CO)R^{k}, wherein R^{k} is hydrogen, deuterium, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof),
R^{a} and Rⁱ are each independently substituted with at least one deuterium,
R^{b} and R^{k} are each independently deuterium or substituted with at least one deuterium, and
at least one selected from R^{e} and R^{d}; at least one selected from R^{e} and R^{f}; and at least one selected from among R^{g}, R^{h}, and Rⁱ are each independently deuterium or are each independently substituted with at least one deuterium.

4. The semiconductor photoresist composition as claimed in claim 2, wherein:
X is selected from among an alkoxy or aryloxy group (—OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{b}, wherein R^{b} is hydrogen, deuterium, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and an amidato group (—NR^{e}(COR^{f}), wherein R^{e} and R^{f} are each independently hydrogen, deuterium, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof),
R^{a} is substituted with at least one deuterium,
R^{b} is deuterium or substituted with at least one deuterium, and
at least one selected from R^{e} and R^{f} is each independently deuterium or is each independently substituted with at least one deuterium.

5. The semiconductor photoresist composition as claimed in claim 2, wherein:
R^{a} and Rⁱ are each independently a methyl group substituted with at least one deuterium, an ethyl group substituted with at least one deuterium, a propyl group substituted with at least one deuterium, a butyl group substituted with at least one deuterium, an isopropyl group substituted with at least one deuterium, a tert-butyl group substituted with at least one deuterium, a tert-pentyl group substituted with at least one deuterium, a 2,2-dimethylpropyl group substituted with at least one deuterium, a cyclopropyl group substituted with at least one deuterium, a cyclobutyl group substituted with at least one deuterium, a cyclopentyl group substituted with at least one deuterium, a cyclohexyl group substituted with at least one deuterium, an ethenyl group substituted with at least one deuterium, a propenyl group substituted with at least one deuterium, a butenyl group substituted with at least one deuterium, an ethynyl group substituted with at least one deuterium, a propynyl group substituted with at least one deuterium, a butynyl group substituted with at least one deuterium, a phenyl group substituted with at least one deuterium, a tolyl group substituted with at least one deuterium, a xylene group substituted with at least one deuterium, a benzyl group substituted with at least one deuterium, or a combination thereof,
R^{b} and R^{k} are each independently deuterium, a methyl group substituted with at least one deuterium, an ethyl group substituted with at least one deuterium, a propyl group substituted with at least one deuterium, a butyl group substituted with at least one deuterium, an isopropyl group substituted with at least one deuterium, a tert-butyl group substituted with at least one deuterium, a tert-pentyl group substituted with at least one deuterium, a 2,2-dimethylpropyl group substituted with at least one deuterium, a cyclopropyl group substituted with at least one deuterium, a cyclobutyl group substituted with at least one deuterium, a cyclopentyl group substituted with at least one deuterium, a cyclohexyl group substituted with at least one deuterium, an ethenyl group substituted with at least one deuterium, a propenyl group substituted with at least one deuterium, a butenyl group substituted with at least one deuterium, an ethynyl group substituted with at least one deuterium, a propynyl group substituted with at least one deuterium, a butynyl group substituted with at least one deuterium, a phenyl group substituted with at least one deuterium, a tolyl group substituted with at least one deuterium, a xylene group substituted with at least one deuterium, a benzyl group substituted with at least one deuterium, or a combination thereof,
R^{c}, R^{d}, R^{e}, R^{f}, R^{g}, R^{h}, and Rⁱ are each independently hydrogen, deuterium, a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted tert-pentyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof, and
at least one selected from R^{c} and R^{d}; at least one selected from R^{e} and R^{f}; and at least one selected from among R^{g}, R^{h}, and Rⁱ are each independently deuterium, a methyl group substituted with at least one deuterium, an ethyl group substituted with at least one deuterium, a propyl group substituted with at least one deuterium, a butyl group substituted with at least one deuterium, an isopropyl group substituted with at least one deuterium, a tert-butyl group substituted with at least one deuterium, a tert-pentyl group substituted with at least one deuterium, a 2,2-dimethylpropyl group substituted with at least one deuterium, a cyclopropyl group substituted with at least one deuterium, a cyclobutyl group substituted with at least one deuterium, a cyclopentyl group substituted with at least one deuterium, a cyclohexyl group substituted with at least one deuterium, an ethenyl group substituted with at least one deuterium, a propenyl group substituted with at least one deuterium, a butenyl group substituted with at least one deuterium, an ethynyl group substituted with at least one deuterium, a propynyl group substituted with at least one deuterium, a butynyl group substituted with at least one deuterium, a phenyl group substituted with at least one deuterium, a tolyl group substituted with at least one deuterium, a xylene group substituted with at least one deuterium, a benzyl group substituted with at least one deuterium, or a combination thereof.

6. The semiconductor photoresist composition as claimed in claim 1, wherein:
a deuterium substitution ratio of the hydrolyzable ligand is about 1 to about 100%.

7. The semiconductor photoresist composition as claimed in claim 1, wherein:
the hydrolyzable ligand is one or more functional groups derived from propionic acid, 4-methyl-2-pentanol (MIBC), propylene glycol monomethyl ether acetate (PGMEA), propylene glycol monomethyl ether (PGME), furoic acid, diethyl amine, and methyl isobutyrate.

8. The semiconductor photoresist composition as claimed in claim 1, wherein:
an amount of the organic tin (Sn) compound is about 0.5 wt % to about 30 wt % based on 100 wt % of the semiconductor photoresist composition.

9. The semiconductor photoresist composition as claimed in claim 1, wherein:
the semiconductor photoresist composition further comprises an additive of a surfactant, a crosslinking agent, a leveling agent, an organic acid, a quencher, or a combination thereof.

10. A method of forming patterns, comprising:
providing an etching-objective layer on a substrate;
coating the semiconductor photoresist composition as claimed in claim 1 on the etching-objective layer and heating it at a temperature of about 110° C. to about 180° C. to form a photoresist layer;
exposing and developing the photoresist layer to form a photoresist film having a photoresist pattern; and
etching the etching-objective layer using the photoresist pattern as an etching mask.

11. The method as claimed in claim 10, wherein:
the root mean square roughness (R^{a}) of the photoresist layer is less than about 0.4.

12. The method as claimed in claim 10, wherein:
the photoresist layer comprises a tin (Sn)-oxygen (O)-tin (Sn) bond and a tin (Sn)-oxygen (O)-deuterium (D) bond.

13. The method as claimed in claim 10, wherein
after exposing, the photoresist pattern comprises a tin (Sn)-oxygen (O)-tin (Sn) bond and a tin (Sn)-oxygen (O)-deuterium (D) bond.
